(19) United States
(12) Patent Application Publication
(10) Pub. No.: US 2012/0256265 A1
(43) Pub. Date: Oct. 11, 2012

(54) SEMICONDUCTOR DEVICE AND MANUFACTURING METHOD THEREOF

(75) Inventor: Hiromasa FUJIMOTO, Toyama (JP)

(73) Assignee: Panasonic Corporation, Osaka (JP)

(21) Appl. No.: 13/495,465

(22) Filed: Jun. 13, 2012

Related U.S. Application Data
(63) Continuation of application No. PCT/JP2010/004764, filed on Jul. 27, 2010.

(30) Foreign Application Priority Data
Jan. 21, 2010 (JP) 2010-010649

(51) Int. Cl. H01L 27/088

(52) U.S. Cl. 257/368; 257/E27.06

(57) ABSTRACT

A first source/drain region is formed outside a first insulating sidewall spacer, as viewed from a first gate electrode, in a semiconductor substrate. A second source/drain region is formed outside a second insulating sidewall spacer, as viewed from a second gate electrode, in the semiconductor substrate. The second source/drain region includes a silicon mixed-crystal layer. The second gate electrode has a lower height than the first gate electrode.

### CROSS-REFERENCE TO RELATED APPLICATION

This is a continuation of PCT International Application PCT/JP2010/004764 filed on Jul. 27, 2010, which claims priority to Japanese Patent Application No. 2010-010649 filed on Jan. 21, 2010. The disclosures of these applications including the specifications, the drawings, and the claims are hereby incorporated by reference in their entirety.

### BACKGROUND

The present disclosure relates to semiconductor devices and manufacturing methods thereof, and more particularly to semiconductor devices that improve driving capability of a transistor by a strain technique using a silicon mixed-crystal layer provided in a source/drain region of a metal-insulator-semiconductor field effect transistor (MISFET), and manufacturing methods thereof

A strain technique in which driving capability of a transistor is improved by applying stress to a channel region of a MISFET (hereinafter referred to as the “MIS transistor”) is used in order to improve performance of semiconductor integrated circuit devices. For example, it is known that carrier mobility in a P-type MIS transistor is enhanced by applying compressive stress to a channel region thereof in a gate length direction. One method of applying compressive stress to the channel region of the P-type MIS transistor is to form in a source/drain region a silicon germanium (SiGe) layer having a larger lattice constant than a silicon substrate (see, e.g., Japanese Patent Publication No. 2006-196549, T. Ghani et al., “A 90 nm High Volume Manufacturing Logic Technology Featuring Novel 45 nm Gate Length Strained Silicon CMOS Transistors,” IEDM Tech. Digest, 2003, pp. 978-980, and Z. Luo et al., “Design of High Performance PFETs with Strained Si Channel and Laser Anneal,” IEDM Tech., Digest, 2005, pp. 495-498.)

As a manufacturing method of a conventional semiconductor device using the strain technique, a manufacturing method of a semiconductor device which includes a complementary metal-insulator semiconductor (CMIS) element formed by N-type and P-type MIS transistors provided on the same substrate, and which has in a source/drain formation region of the P-type MIS transistor a silicon mixed-crystal layer comprised of a SiGe layer will be described below with reference to the accompanying drawings.

FIGS. 5A-5D, 6A-6C, and 7A-7C are cross-sectional views in the gate length direction, showing each step of the manufacturing method of the conventional semiconductor device.

First, as shown in FIG. 5A, after a P-type well region 502A is formed in an active region of an N-type MIS transistor formation region Rₙ surrounded by an isolation region 501 in a semiconductor substrate 500, a gate electrode 504A is formed on the P-type well region 502A with a gate insulating film 503A interposed therebetween. After an N-type well region 502B is formed in an active region of a P-type MIS transistor formation region Rₚ surrounded by the isolation region 501 in the semiconductor substrate 500, a gate electrode 504B is formed on the N-type well region 502B with a gate insulating film 503B interposed therebetween. Hard masks 505A, 505B comprised of a silicon nitride (SiN) film are formed on the gate electrodes 504A, 504B, respectively. The gate electrodes 504A, 504B have a stacked structure of a lower metal film and an upper silicon film.

Next, as shown in FIG. 5A, insulating offset spacers 506A, 506B comprised of a silicon dioxide (SiO₂) film are formed on the side surfaces of the gate electrode 504A and the hard mask 505A and on the side surfaces of the gate electrode 504B and the hard mask 505B, respectively. Then, an N-type extension region 507A is formed on both sides of the gate electrode 504A in a surface portion of the P-type well region 502A. A P-type extension region 507B is formed on both sides of the gate electrode 504B in a surface portion of the N-type well region 502B.

Then, as shown in FIG. 5B, after a silicon nitride film is deposited over the entire surface of the semiconductor substrate 500, etchback is performed on the silicon nitride film. Thus, an insulating sidewall spacer 508A is formed on the side surfaces of the gate electrode 504A and the hard mask 505A with the insulating offset spacer 506A interposed therebetween, and an insulating sidewall spacer 508B is formed on the side surfaces of the gate electrode 504B and the hard mask 505B with the insulating offset spacer 506B interposed therebetween.

Then, as shown in FIG. 5C, by using as a mask a resist pattern 509 having an opening on the N-type MIS transistor formation region Rₙ, arsenic ions 510 are implanted to form an N-type source/drain region 511A on both sides of the insulating sidewall spacer 508A, as viewed from the gate electrode 504A, in the P-type well region 502A.

Then, as shown in FIG. 5D, after the resist pattern 509 is removed, a silicon oxide film 512 and a silicon nitride film 513 are sequentially deposited over the entire surface of the semiconductor substrate 500.

Then, as shown in FIG. 6A, after a resist pattern 514 having an opening on the P-type MIS transistor formation region Rₚ is formed by a photolithography process, the silicon oxide film 512 and the silicon nitride film 513 on the P-type MIS transistor formation region Rₚ are etched away by using the resist pattern 514 as a mask.

Then, as shown in FIG. 6B, by using the resist pattern 514 as a mask, anisotropic dry etching is performed on the semiconductor substrate 500 to form a recessed portion 515 on both sides of the insulating sidewall spacer 508B, as viewed from the gate electrode 504B, in the N-type well region 502B.

Then, as shown in FIG. 6C, after the resist pattern 514 is removed, silicon germanium doped with P-type impurities is selectively epitaxially grown in the recessed portion 515 to form a silicon germanium layer 516 that serves as a P-type source/drain region 511B.

Then, as shown in FIG. 7A, after a resist pattern 517 having an opening on the N-type MIS transistor formation region Rₙ is formed, the silicon oxide film 512 and the silicon nitride film 513 on the N-type MIS transistor formation region Rₙ are etched away by using the resist pattern 517 as a mask.

Then, as shown in FIG. 7B, after the resist pattern 517 is removed, the insulating sidewall spacer 508A and the hard mask 505A, which are respectively formed over the side surface of the gate electrode 504A and on the upper surface of the gate electrode 504A, and the insulating sidewall spacer 508B and the hard mask 505B, which are respectively formed over the side surface of the gate electrode 504B and on the upper surface of the gate electrode 504B, are etched away.

Then, as shown in FIG. 7C, after a silicon oxide film is deposited over the entire surface of the semiconductor substrate 500, etchback is performed on the silicon oxide film. Thus, an insulating sidewall spacer 518A is formed on the side surface of the gate electrode 504A with the insulating offset spacer 506A interposed therebetween, and an insulating sidewall spacer 518B is formed on the side surface of the gate electrode 504B with the insulating offset spacer 506B interposed therebetween.

Lastly, as shown in FIG. 7C, after nickel is deposited over the entire surface of the semiconductor substrate 500, a heat treatment is performed to cause silicon in the N-type source/drain region 511A and the P-type source/drain region 511B and silicon in the upper portions of the gate electrodes 504A, 504B to react with nickel, thereby forming a silicide layer. Then, unreacted nickel is removed. Thus, silicide layers 519A, 519B are formed on the N-type source/drain region 511A and the P-type source/drain region 511B, respectively, and silicide layers 519C, 519D are formed on the gate electrodes 504A, 504B, respectively.

A CMIS transistor in which only the P-type source/drain region 511B is comprised of the silicon germanium layer 516 can be formed by the above process flow.

### SUMMARY

Compressive stress that is applied from a silicon mixed-crystal layer comprised of a silicon germanium layer to a channel region typically improves driving capability of a P-type transistor, but reduces driving capability of an N-type transistor. Accordingly, a semiconductor device of a CMIS structure having an N-type transistor and a P-type transistor on the same substrate need be configured so that a SiGe layer is formed in a source/drain formation region of the P-type transistor and that no SiGe layer is formed in a source/drain formation region of the N-type transistor.

Accordingly, the following technique is used in the above manufacturing method of the conventional semiconductor device in order to prevent epitaxial growth of the silicon germanium layer in the N-type transistor formation region. After the insulating film is deposited over the entire surface of the semiconductor substrate as shown in FIG. 5D, only the insulating film on the P-type transistor formation region is etched away as shown in FIG. 6A. Then, after an exposed portion of the semiconductor substrate in the P-type transistor formation region is recessed by etching as shown in FIG. 6B, the silicon germanium layer is selectively epitaxially grown in the recessed portion.

However, in the above manufacturing method of the conventional semiconductor device, the hard mask configured to prevent selective epitaxial growth on the gate electrode is present also on the gate electrode in the N-type transistor formation region. Accordingly, no impurity is implanted into the silicon in the upper portion of the gate electrode in the N-type transistor formation region in the step (the ion implantation step for forming the source/drain region of the N-type transistor) shown in FIG. 5C, and thus the resistance of the gate electrode of the N-type transistor is increased.

Moreover, in the step shown in FIG. 7B in the above manufacturing method of the conventional semiconductor device, the insulating sidewall spacers are simultaneously removed when removing the hard masks on the gate electrodes. Accordingly, in the step shown in FIG. 7C, insulating sidewall spacers need be formed again on the side surfaces of the gate electrodes in order to form a silicide layer in a predetermined region, and thus the number of steps is increased.

In view of the above problems, it is an object of the present disclosure to improve performance of a semiconductor device by a strain technique using a silicon mixed-crystal layer, without increasing the gate electrode resistance and the number of steps.

In order to achieve the above-mentioned object, the inventor of the present application conducted various studies and arrived at the invention of forming a recessed portion of a semiconductor substrate, in which a silicon mixed-crystal layer serving as a source/drain region is to be embedded, without providing a hard mask on the gate electrodes as in the related art.

Specifically, a semiconductor device according to the present disclosure is a semiconductor device including a semiconductor substrate having thereon a first MIS transistor and a second MIS transistor that are separated from each other by an isolation region. The first MIS transistor includes a first active region surrounded by the isolation region in the semiconductor substrate, a first gate insulating film formed on the first active region, a first gate electrode formed on the first gate insulating film, a first insulating sidewall spacer formed on a side surface of the first gate electrode, and a first source/drain region formed outside the first insulating sidewall spacer, as viewed from the first gate electrode, in the first active region. The second MIS transistor includes a second active region surrounded by the isolation region in the semiconductor substrate, a second gate insulating film formed on the second active region, a second gate electrode formed on the second gate insulating film, a second insulating sidewall spacer formed on a side surface of the second gate electrode, and a second source/drain region formed outside the second insulating sidewall spacer, as viewed from the second gate electrode, in the second active region. The second source/drain region includes a silicon mixed-crystal layer, and the second gate electrode has a lower height than the first gate electrode.

That is, in the semiconductor device according to the present disclosure, the silicon mixed-crystal layer that serves as the second source/drain region of the second MIS transistor is formed without providing a hard mask on the gate electrode as in the related art. Accordingly, an upper portion of the second gate electrode of the second MIS transistor is removed when forming a recessed portion of the semiconductor substrate in which the silicon mixed-crystal layer is to be embedded. As a result, the height of the second gate electrode is lower than that of the first gate electrode of the first MIS transistor.

According to the semiconductor device of the present disclosure, no hard mask configured to prevent selective epitaxial growth on the gate electrode is present on the first gate electrode. Accordingly, in the case where, e.g., at least an upper portion of the first gate electrode is comprised of silicon, impurities are introduced also into the silicon in the upper portion of the first gate electrode when forming the first source/drain region of the first MIS transistor. Thus, resistance of the first gate electrode can be reduced.

Since no hard mask is provided on the gate electrodes, the step of removing the hard masks from the gate electrodes as in the related art is not required. Thus, the insulating sidewall spacers can be prevented from being removed in this step. This eliminates the need for the step of forming the insulating sidewall spacers again, which is required in the related art to perform the silicidation process on the source/drain regions. Accordingly, the number of steps is not increased.

Moreover, since the height of the second gate electrode of the second MIS transistor is lower than that of the first gate electrode of the first MIS transistor, the semiconductor device having different gate electrode heights between the first MIS transistor and the second MIS transistor can be manufactured. Accordingly, optimal stress in a vertical direction (a direction perpendicular to the principal surface of the substrate) can be applied to the channel region of each transistor by using a liner insulating film, whereby driving capability of each transistor can be improved.

As described above, according to the semiconductor device of the present disclosure, performance of the semiconductor device can be improved by a strain technique using a silicon mixed-crystal layer, without increasing the gate electrode resistance and the number of steps.

In the semiconductor device of the present disclosure, the first gate electrode may have a first metal-containing layer, and a silicon layer formed on the first metal-containing layer and containing the same impurities as the first source/drain region, the second gate electrode may have a second metal-containing layer, a metal silicide layer may be formed on the first gate electrode, and an alloy layer may be formed on the second gate electrode. The alloy layer formed on the second gate electrode may be comprised of an alloy of a metal contained in the metal silicide layer formed on the first gate electrode and a metal contained in the second metal-containing layer that serves as the second gate electrode.

In the semiconductor device of the present disclosure, a metal silicide layer may be formed on each of the first and second source/drain regions. The metal silicide layer formed on each of the first and second source/drain regions may be the same metal silicide layer as that formed on the first gate electrode.

The semiconductor device of the present disclosure may further include: a first extension region formed below the first insulating sidewall spacer in the first active region; and a second extension region formed below the second insulating sidewall spacer in the second active region.

In the semiconductor device of the present disclosure, the first insulating sidewall spacer may include a first L-shaped inner sidewall spacer, and the second insulating sidewall spacer may include a second L-shaped inner sidewall spacer. In this case, each of the first and second L-shaped inner sidewall spacers may be comprised of a silicon oxide film. The second L-shaped inner sidewall spacer may have a lower height than the first L-shaped inner sidewall spacer. The height of the second L-shaped inner sidewall spacer may be equal to or greater than that of the second gate electrode (in the case where the alloy layer is formed on the second gate electrode, the height of the stacked structure of the second gate electrode and the alloy layer). The first insulating sidewall spacer may include a first outer sidewall spacer that covers the first L-shaped inner sidewall spacer, and the second insulating sidewall spacer may include a second outer sidewall spacer that covers the second L-shaped inner sidewall spacer. In this case, each of the first and second outer sidewall spacers may be comprised of a silicon nitride film.

Although each of the first and second insulating sidewall spacers may have a structure of three layers or more including the L-shaped inner sidewall spacer and the outer sidewall spacer, it is preferable that the lowermost layer be the L-shaped inner sidewall spacer.

The semiconductor device of the present disclosure may further include: a first insulating offset spacer formed between the side surface of the first gate electrode and the first insulating sidewall spacer; and a second insulating offset spacer formed between the side surface of the second gate electrode and the second insulating sidewall spacer. In this case, each of the first and second insulating offset spacers may be comprised of a silicon oxide film. The second insulating offset spacer may have a lower height than the first insulating offset spacer. The height of the second insulating offset spacer may be equal to or greater than that of the second gate electrode (in the case where the alloy layer is formed on the second gate electrode, the height of the stacked structure of the second gate electrode and the alloy layer).

In the semiconductor device of the present disclosure, a part of the silicon mixed-crystal layer may overlap the second insulating sidewall spacer. This allows stress to be effectively applied from the silicon mixed-crystal layer to the channel region of the second MIS transistor. Thus, performance of the semiconductor device can further be improved.

In the semiconductor device of the present disclosure, a top portion of the silicon mixed-crystal layer may be located higher than an upper surface of the semiconductor substrate which serves as the second active region. This can reduce the difference in height between the second gate electrode and the top portion of the silicon mixed-crystal layer (in the case where a metal silicide layer is formed on the silicon mixed-crystal layer, a top portion of the metal silicide layer). Accordingly, even if the second MIS transistor is a P-type MIS transistor, and an insulating film that produces tensile stress is formed on the second gate electrode, the tensile stress that is applied to the channel region of the P-type MIS transistor can be reduced, and thus degradation in characteristics of the P-type MIS transistor can be suppressed. Alternatively, even if the second MIS transistor is an N-type MIS transistor, and an insulating film that produces compressive stress is formed on the second gate electrode, the compressive stress that is applied to the channel region of the N-type MIS transistor can be reduced, and thus degradation in characteristics of the N-type MIS transistor can be suppressed.

In the semiconductor device of the present disclosure, the semiconductor substrate may be a silicon substrate, the second MIS transistor may be a P-type MIS transistor, and the silicon mixed-crystal layer may be a SiGe layer. This allows compressive stress to be applied to the channel region of the P-type MIS transistor in a gate length direction. Accordingly, carrier mobility is enhanced, and performance can be improved.

In the semiconductor device of the present disclosure, the semiconductor substrate may be a silicon substrate, the second MIS transistor may be an N-type MIS transistor, and the silicon mixed-crystal layer may be a SiC layer. This allows tensile stress to be applied to the channel region of the N-type MIS transistor in the gate length direction. Accordingly, carrier mobility is enhanced, and performance can be improved.

In the semiconductor device of the present disclosure, an insulating layer that produces stress in an opposite direction to that of stress of the silicon mixed-crystal layer may be formed to cover the first and second MIS transistors. In this case, since the height of the second gate electrode of the second MIS transistor is lower than that of the first gate electrode of the first MIS transistor, stress that is applied from the insulating film to the channel region of the second MIS transistor in the gate length direction can be reduced. Since the effect of the stress that is applied from the silicon mixed-crystal layer to the channel region of the second MIS transistor is not eliminated, degradation in characteristics of the second MIS transistor can suppressed. Thus, the step of removing from the second MIS transistor the insulating layer that produces stress in the opposite direction to that of the stress of the silicon mixed-crystal layer can be omitted. In this case, the insulating film may be a silicon nitride film. The second MIS transistor may be a P-type MIS transistor, and the insulating layer may produce tensile stress. Alternatively, the second MIS transistor may be an N-type MIS transistor, and the insulating layer may produce compressive stress.

In the case where the insulating sidewall spacer of each transistor is formed only by the L-shaped inner sidewall spacer, it is preferable that the insulating film that produces stress in the opposite direction to that of the stress of the silicon mixed-crystal layer be formed to cover a bent portion of the L-shaped inner sidewall spacer. This allows the stress to be more effectively applied from the insulating layer to the channel region of the first MIS transistor, and thus characteristics of the first MIS transistor can be improved.

A manufacturing method of a semiconductor device according to the present disclosure is a manufacturing method of a semiconductor device including a semiconductor substrate having thereon a first MIS transistor and a second MIS transistor that are separated from each other by an isolation region. The method includes the steps of: (a) forming a first active region of the first MIS transistor surrounded by the isolation region and a second active region of the second MIS transistor surrounded by the isolation region in the semiconductor substrate; (b) forming a first gate electrode and a second gate electrode on the first and second active regions, respectively; (c) forming a first insulating sidewall spacer and a second insulating sidewall spacer on a side surface of the first gate electrode and a side surface of the second gate electrode, respectively; (d) after the step (c), forming a first source/drain region outside the first insulating sidewall spacer, as viewed from the first gate electrode, in the first active region; (e) after the step (d), forming a recessed portion outside the second insulating sidewall spacer, as viewed from the second gate electrode, in the second active region, and partially removing the second gate electrode; and (0 forming in the recessed portion a silicon mixed-crystal layer that serves as a second source/drain region.

According to the manufacturing method of the semiconductor device of the present disclosure, the recessed portion of the semiconductor substrate, in which the silicon mixed-crystal layer serving as the second source/drain region of the second MIS transistor is to be embedded, is formed without forming on the gate electrode of each transistor a hard mask configured to prevent selective epitaxial growth on the gate electrode as in the related art. Thus, in the case where, e.g., at least an upper portion of the first gate electrode is comprised of silicon, impurities are introduced also into the silicon in the upper portion of the first gate electrode when forming the first source/drain region of the first MIS transistor. Thus, resistance of the first gate electrode can be reduced.

Since no hard mask is formed on each gate electrode, the step of removing the hard masks on the gate electrodes as in the related art is not required. Thus, the insulating sidewall spacers can be prevented from being removed in this step. This eliminates the need for the step of forming the insulating sidewall spacers again, which is required in the related art to perform the silicidation process on the source/drain regions. Accordingly, the number of steps is not increased.

Moreover, since an upper portion of the second gate electrode of the second MIS transistor is removed when forming the recessed portion of the semiconductor substrate in which the silicon mixed-crystal layer is to be embedded, the height of the second gate electrode is lower than that of the first gate electrode of the first MIS transistor. Thus, the semiconductor device having different gate electrode heights between the first MIS transistor and the second MIS transistor can be manufactured. Accordingly, optimal stress in a vertical direction (a direction perpendicular to the principal surface of the substrate) can be applied to the channel region of each transistor by using a liner insulating film, whereby driving capability of each transistor can be improved.

As described above, according to the manufacturing method of the semiconductor device of the present disclosure, performance of the semiconductor device can be improved by a strain technique using a silicon mixed-crystal layer, without increasing the gate electrode resistance and the number of steps.

In the manufacturing method of the semiconductor device of the present disclosure, the step (b) may include the step of forming as the first gate electrode a first metal-containing layer and a first silicon layer formed on the first metal-containing layer, and forming as the second gate electrode a second metal-containing layer and a second silicon layer formed on the second metal-containing layer. The step (d) may include the step of introducing the same impurities as those of the first source/drain region into the first silicon layer of the first gate electrode. The step (e) may include the step of removing the second silicon layer of the second gate electrode, and may further include, after the step (f), the step of forming a metal silicide layer on each of the first source/drain region, the second source/drain region, and the first gate electrode, and forming an alloy layer on the second gate electrode. The alloy layer that is formed on the second gate electrode may be comprised of an alloy of a metal contained in the metal silicide layer formed on the first gate electrode and a metal contained in the second metal-containing layer that serves as the second gate electrode.

In the manufacturing method of the semiconductor device of the present disclosure, the step (d) may include the step of forming the first source/drain region by ion implantation by using as a mask a resist pattern having an opening on the first active region of the first MIS transistor. The manufacturing method of the semiconductor device of the present disclosure may further include between the steps (d) and (e) the step of removing the resist pattern.

In the manufacturing method of the semiconductor device of the present disclosure, the step (e) may include the step of forming the recessed portion by using as a mask a protective film having an opening on the second active region of the second MIS transistor, and removing the upper portion of the second gate electrode. The step (f) may include the step of forming the silicon mixed-crystal layer by using the protective film as a mask. The manufacturing method of the semiconductor device of the present disclosure may further include after the step (f) the step of removing the protective film by using as a mask a resist pattern that covers a formation region of the second MIS transistor. In order to silicidize a surface portion of the source/drain region of each transistor, the silicidation process may be performed after removing the protective film.

In the manufacturing method of the semiconductor device of the present disclosure, the step (c) may include the step of forming as the first insulating sidewall spacer a first L-shaped inner sidewall spacer and a first outer sidewall spacer that covers the first L-shaped inner sidewall spacer, and forming as the second insulating sidewall spacer a second L-shaped inner sidewall spacer and a second outer sidewall spacer that covers the second L-shaped inner sidewall spacer. The manufacturing method of the semiconductor device of the present disclosure may further include, after the step (f), the step of removing the first and second outer sidewall spacers, and then forming an insulating film, which produces stress in an opposite direction to that of stress of the silicon mixed-crystal layer, so as to cover the first and second active regions. In this case, since the height of the second gate electrode of the second MIS transistor is lower than that of the first gate electrode of the first MIS transistor, stress that is applied from the insulating film to the channel region of the second MIS transistor in the gate length direction can be reduced. Since the effect of the stress that is applied from the silicon mixed-crystal layer to the channel region of the second MIS transistor is not eliminated, degradation in characteristics of the second MIS transistor can suppressed. Thus, the step of removing from the second MIS transistor the insulating film that produces stress in the opposite direction to that of the stress of the silicon mixed-crystal layer can be omitted.

The insulating layer that produces stress in the opposite direction to that of the stress of the silicon mixed-crystal layer may be formed without removing the outside sidewall spacers. However, in order to effectively apply the stress from the insulating film to the channel region of the first MIS transistor, it is preferable to form the insulating film after removing the outer sidewall spacers. In the case where the insulating film is formed after removing the outer sidewall spacers, it is preferable that the insulating film be formed to cover a bent portion of the L-shaped inner sidewall spacer. This allows the stress to be more effectively applied from the insulating layer to the channel region of the first MIS transistor, and thus characteristics of the first MIS transistor can further be improved.

In the manufacturing method of the semiconductor device of the present disclosure, the step (e) may include the step of forming the recessed portion and removing the upper portion of the second gate electrode by performing etching a plurality of times under different conditions. In this case, since the recessed portion can be formed to overlap the second insulating sidewall spacer, the stress can be effectively applied from the silicon mixed-crystal layer embedded in the recessed portion to the channel region of the second MIS transistor. Thus, performance of the semiconductor device can further be improved.

As described above, the present disclosure can improve performance of a semiconductor device by a strain technique using a silicon mixed-crystal layer, without increasing the gate electrode resistance and the number of steps. Accordingly, the present disclosure is useful as a semiconductor device having a silicon mixed-crystal layer in a source/drain region of an MISFET and a manufacturing method thereof

### BRIEF DESCRIPTION OF THE DRAWINGS

FIGS. 1A-1D are cross-sectional views in a gate length direction, showing the steps of a manufacturing method of a semiconductor device according to a first embodiment.

FIGS. 2A-2D are cross-sectional views in the gate length direction, showing the steps of the manufacturing method of the semiconductor device according to the first embodiment.

FIGS. 3A-3C are cross-sectional views in the gate length direction, showing the steps of the manufacturing method of the semiconductor device according to the first embodiment.

FIGS. 4A-4B are cross-sectional views in a gate length direction, showing the steps of a manufacturing method of a semiconductor device according to a modification of the first embodiment.

FIGS. 5A-5D are cross-sectional views in a gate length direction, showing the steps of a manufacturing method of a conventional semiconductor device.

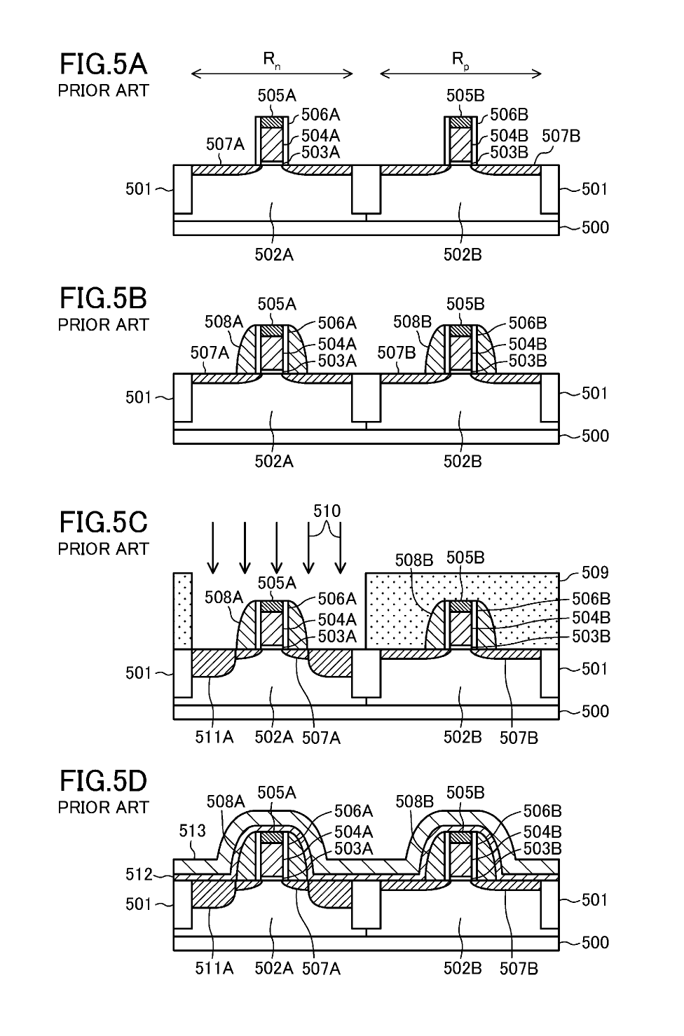

FIGS. 6A-6C are cross-sectional views in the gate length direction, showing the steps of the manufacturing method of the conventional semiconductor device.

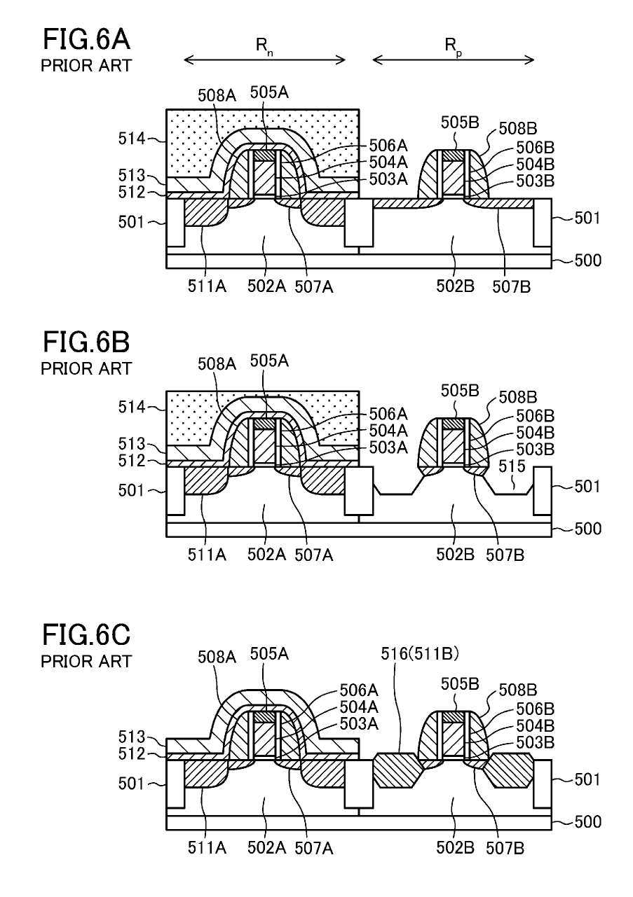

FIGS. 7A-7C are cross-sectional views in the gate length direction, showing the steps of the manufacturing method of the conventional semiconductor device.

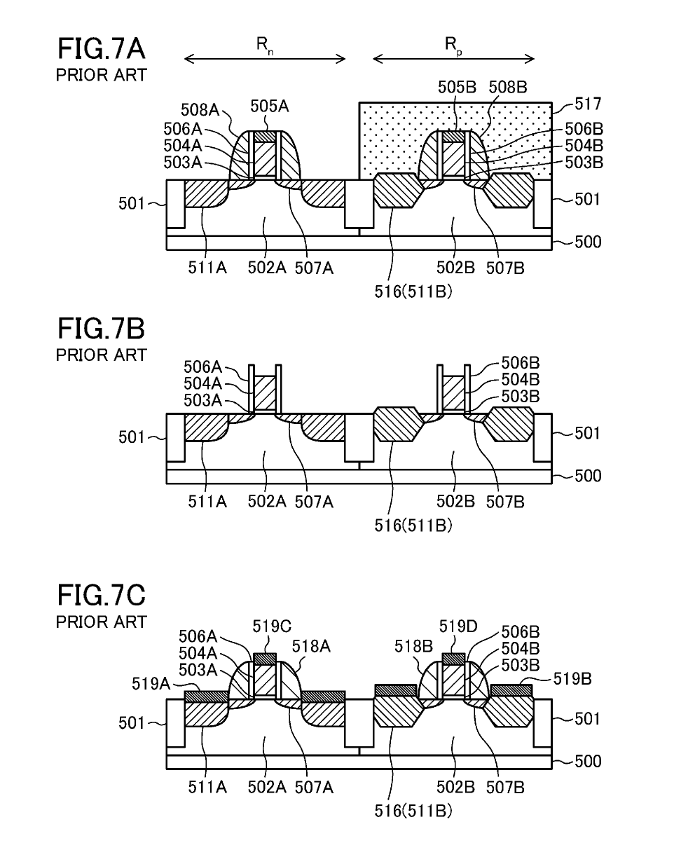

### DETAILED DESCRIPTION

### First Embodiment

A semiconductor device and a manufacturing method thereof according to a first embodiment will be described below with reference to the accompanying drawings.

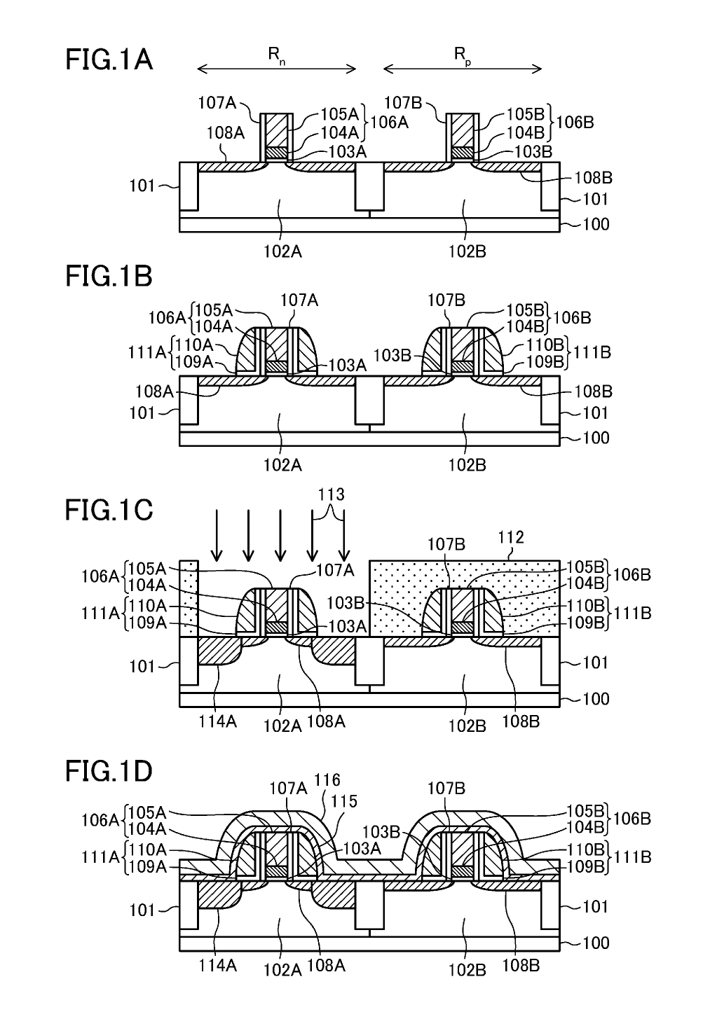

FIGS. 1A-1D, 2A-2D, and 3A-3C are cross-sectional views in a gate length direction, showing the steps of the manufacturing method of the semiconductor device according to the present embodiment.

First, as shown in FIG. 1A, a P-type well region 102A is formed in an active region of an N-type MIS transistor formation region Rₙ surrounded by an isolation region 101 in a semiconductor substrate 100 such as a silicon substrate etc. An N-type well region 102B is formed in an active region of a P-type MIS transistor formation region Rₚ surrounded by the isolation region 101 in the semiconductor substrate 100. Then, a gate electrode 106A is formed on the active region (the P-type well region 102A) of the N-type MIS transistor formation region Rₙ with a gate insulating film 103A interposed therebetween, and a gate electrode 106B is formed on the active region (the N-type well region 102B) of the P-type MIS transistor formation region Rₚ with a gate insulating film 103B interposed therebetween.

Each of the gate insulating films 103A, 103B is comprised of a high dielectric constant (high-k) insulating film such as, e.g., a hafnium oxide (HfO₂) film etc., and an interface layer such as, e.g., a SiO₂ film etc. may be formed below the high-k insulating film.

The gate electrode 106A has a two-layer structure of a metal-containing layer 104A (a lower layer) and a silicon layer 105A (an upper layer). The metal-containing layer 104A is comprised of, e.g., titanium nitride, tantalum nitride, etc., and has a thickness of about 10-30 nm. The silicon layer 105A is comprised of, e.g., non-doped polysilicon, and has a thickness of about 40-60 nm.

Similarly, the gate electrode 106B has a two-layer structure of a metal-containing layer 104B (a lower layer) and a silicon layer 105B (an upper layer). The metal-containing layer 104B is comprised of, e.g., titanium nitride, tantalum nitride, etc., and has a thickness of about 10-30 nm. The silicon layer 105B is comprised of, e.g., non-doped polysilicon, and has a thickness of about 40-60 nm.

Since the non-doped polysilicon is used as the silicon layer 105A of the gate electrode 106A and the silicon layer 105B of the gate electrode 106B, it is not necessary to distinguish the N-type MIS transistor formation region Rₙ from the P-type MIS transistor formation region Rₚ when etching the gate electrodes. This allows the gate electrode 106A of an N-type MIS transistor and the gate electrode 106B of a P-type MIS transistor to be formed with the same dimensions.

Next, as shown in FIG. 1A, insulating offset spacers 107A, 107B each comprised of, e.g., a SiO₂ film are formed on the side surfaces of the gate electrodes 106A, 106B, respectively. Then, an N-type extension region 108A is formed on both sides of the gate electrode 106A in a surface portion of the active region (the P-type well region 102A) of the N-type MIS transistor formation region Rₙ. Moreover, a P-type extension region 108B is formed on both sides of the gate electrode 106B in a surface portion of the active region (the N-type well region 102B) of the P-type MIS transistor formation region Rₚ.

Next, as shown in FIG. 1B, after a silicon oxide film and a silicon nitride film are sequentially deposited over the entire surface of the semiconductor substrate 100, etchback is performed to the silicon oxide film and the silicon nitride film. Thus, an insulating sidewall spacer 111A is formed on the side surface of the gate electrode 106A with the insulating offset spacer 107A interposed therebetween, and an insulating sidewall spacer 111B is formed on the side surface of the gate electrode 106B with the insulating offset spacer 107B interposed therebetween. The insulating sidewall spacer 111A has an L-shaped inner sidewall spacer 109A comprised of the silicon oxide film, and an outer sidewall spacer 110A comprised of the silicon nitride film and covering the L-shaped inner sidewall spacer 109A. The insulating sidewall spacer 111B has an L-shaped inner sidewall spacer 109B comprised of the silicon oxide film, and an outer sidewall spacer 110B comprised of the silicon nitride film and covering the L-shaped inner sidewall spacer 109B. In the case where the gate electrodes 106A, 106B have a gate length of, e.g., about 30 nm, the deposition thickness of the silicon oxide film that serves as the L-shaped inner sidewall spacers 109A, 109B is preferably about 5-10 nm, and the deposition thickness of the silicon nitride film that serves as the outer sidewall spacers 110A, 110B is preferably about 40-60 nm. Although the insulating sidewall spacer 111A may have a structure of three or more layers including the L-shaped inner sidewall spacer 109A and the outer sidewall spacer 110A, it is preferable that the lowermost layer be the L-shaped inner sidewall spacer. Similarly, although the insulating sidewall spacer 111B may have a structure of three or more layers including the L-shaped inner sidewall spacer 109B and the outer sidewall spacer 110B, it is preferable that the lowermost layer be the L-shaped inner sidewall spacer.

Next, as shown in FIG. 1C, after a resist pattern 112 having an opening on the N-type MIS transistor formation region Rₙ (a region including the active region and a part of the isolation region 101 around the active region) is formed by a photolithography process, N-type impurity ions 113 such as, e.g., arsenic ions etc. are implanted by using the resist pattern 112 as a mask. Thus, an N-type source/drain region 114A is formed on both sides of the insulating sidewall spacer 111A, as viewed from the gate electrode 106A, in the P-type well region 102A. It is desirable that this implantation be performed under the conditions of, e.g., acceleration energy of about 10-30 keV and a dose of about 3×10¹⁵ to 8×10¹⁵ cm⁻³. The N-type impurity ions 113 are implanted into the silicon layer 105A of the gate electrode 106A as well when forming the N-type source/drain region 114A. As a result, in the case where the silicon layer 105A before the ion implantation is, e.g., a non-doped polysilicon layer, the silicon layer 105A after the ion implantation is an N-type polysilicon layer.

Then, as shown in FIG. 1D, after the resist pattern 112 is removed, a lower protective film 115 comprised of a silicon oxide film having a thickness of, e.g., about 5-15 nm and an upper protective film 116 comprised of a silicon nitride film having a thickness of, e.g., about 20-50 nm are sequentially deposited over the entire surface of the semiconductor substrate 100.

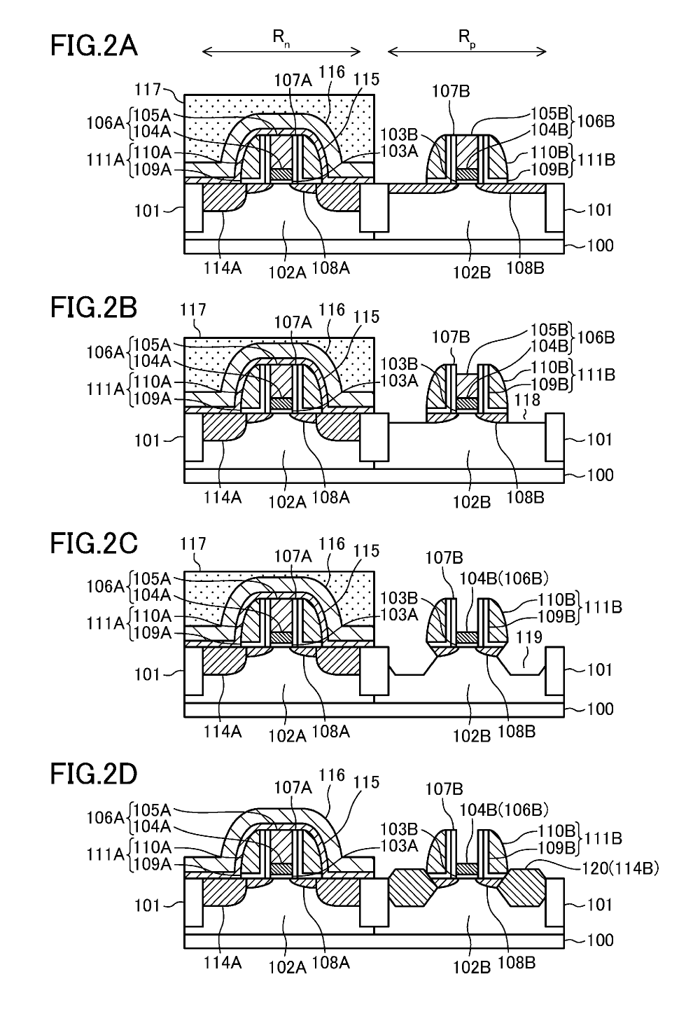

Then, as shown in FIG. 2A, a resist pattern 117 having an opening on the P-type MIS transistor formation region Rₚ (a region including the active region and a part of the isolation region 101 around the active region) is formed by a photolithography process. Thereafter, the lower protective film 115 and the upper protective film 116 on the P-type MIS transistor formation region Rₚ (the region including the active region and a part of the isolation region 101 around the active region) are etched away by using the resist pattern 117 as a mask.

Then, as shown in FIG. 2B, by using the resist pattern 117 as a mask, first anisotropic dry etching is performed on the active region (the semiconductor substrate 100) of the P-type MIS transistor formation region Rₚ by using, e.g., mixed gas of hydrogen bromide (HBr) and nitrogen (N₂). Thus, a first recessed portion 118 having a depth of, e.g., about 10-30 nm is formed on both sides of the insulating sidewall spacer 111B, as viewed from the gate electrode 106B, in the active region (the semiconductor substrate 100) of the P-type MIS transistor formation region Rₚ. At this time, the silicon layer 105B of the gate electrode 106B is also etched by a thickness that is about the same as the depth of the first recessed portion 118. The first anisotropic etching is performed under the conditions of, e.g., a bias voltage of about 100 W and a HBr to N₂ flow ratio of about 10:1.

Then, as shown in FIG. 2C, by using the resist pattern 117 as a mask, second anisotropic etching is performed on the active region of the P-type MIS transistor formation region Rₚ having the first recessed portion 118 formed therein, by using, e.g., mixed gas of HBr and N₂. Thus, a second recessed portion 119 having a depth of, e.g., 50-80 nm is formed on both sides of the insulating sidewall spacer 111B, as viewed from the gate electrode 106B, in the active region of the P-type MIS transistor formation region Rₚ. At this time, the silicon layer 105B of the gate electrode 106B is etched away to expose the metal-containing layer 104B as the gate electrode 106B. That is, the height of the gate electrode 106B comprised substantially only of the metal-containing layer 104B is lower than that of the gate electrode 106A comprised of the metal-containing layer 104A and the silicon layer 105A. The second anisotropic etching is preferably performed under the conditions using lower power and causing less damage as compared to the conditions of the first anisotropic dry etching. Specifically, the second anisotropic etching is performed under the conditions of, e.g., a bias voltage of about 20 W and a HBr to N₂ flow ratio of about 1:1.

In the present embodiment, the second recessed portion 119 serving as a formation region of a P-type source/drain region is formed by performing etching a plurality of times under different conditions. Thus, the second recessed portion 119 can be formed to overlap the insulating sidewall spacer 111B over the side surface of the gate electrode 106B. This allows stress to be effectively applied from the silicon mixed-crystal layer that is embedded in the second recessed portion 119 in a later step to a channel region of the P-type MIS transistor, whereby performance of the semiconductor device can further be improved.

In the present embodiment, anisotropic dry etching is performed twice under different conditions to form the second recessed portion 119. Alternatively, however, anisotropic dry etching may be performed three or more times under different conditions. It should be understood that although anisotropic dry etching is performed a plurality of times to form the second recessed portion 119 in the present embodiment, similar effects can be produced even if anisotropic wet etching is performed a plurality of times.

Then, as show in FIG. 2D, after the resist pattern 117 is removed, a silicon mixed-crystal layer 120 doped with P-type impurities, for example, a silicon germanium layer, is formed as a P-type source/drain region 114B in the second recessed portion 119 by selective epitaxial growth using, e.g., a chemical vapor deposition (CVD) method, by using the lower protective film 115 and the upper protective film 116, which remain on the N-type MIS transistor formation region Rₙ (the region including the active region and a part of the isolation region 101 around the active region), as a mask.

In the present embodiment, the P-type impurities contained in the silicon mixed-crystal layer 120 that serves as the P-type source/drain region 114B may diffuse into the semiconductor substrate 100 around the second recessed portion 119 by a heat treatment for impurity activation in a later step, etc. In other words, the P-type source/drain region 114B may be formed to extend even in the semiconductor substrate 100 (the active region) around the second recessed portion 119.

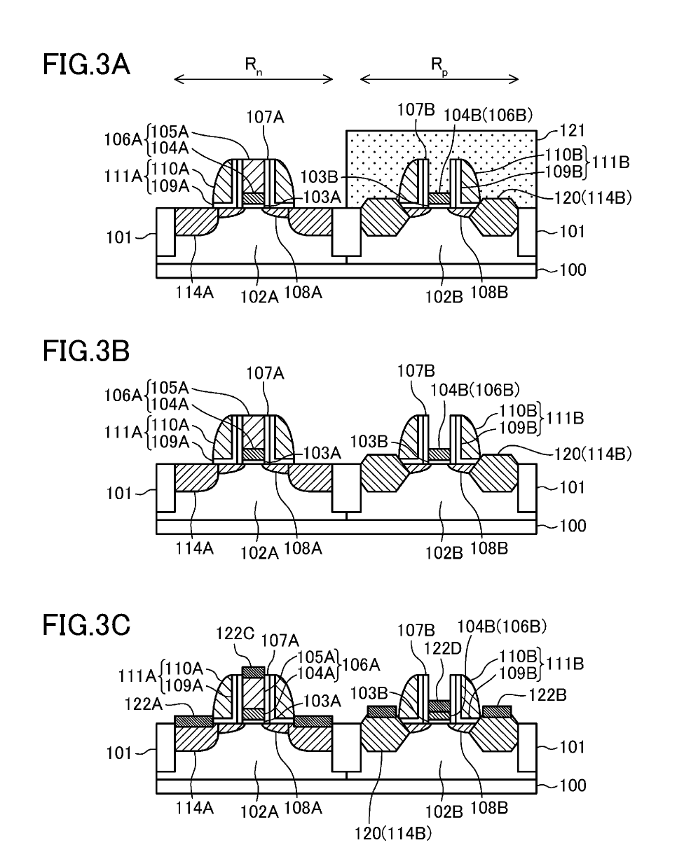

In the present embodiment, the silicon mixed-crystal layer 120 may be formed to extend to a height above the surface of the semiconductor substrate 100. That is, the top portion of the silicon mixed-crystal layer 120 may be located above the upper surface of the semiconductor substrate 100. This can reduce the difference in height between the gate electrode 106B (precisely, a gate electrode structure including an alloy layer 122D (see FIG. 3C) to be formed on the gate electrode 106B in a later step and the insulating sidewall spacer 111B) and the top portion of the silicon mixed-crystal layer 120 (precisely, the top portion of a metal silicide layer 122B (see FIG. 3C) that is formed on the silicon mixed-crystal layer 120 in a later step). Accordingly, even if an insulating film that produces tensile stress is formed on the gate electrode 106B in a later step, the tensile stress that is applied to the channel region of the P-type MIS transistor can be reduced, and thus degradation in characteristics of the P-type MIS transistor can be suppressed.

Then, as shown in FIG. 3A, a resist pattern 121 having an opening on the N-type MIS transistor formation region Rₙ (the region including the active region and a part of the isolation region 101 around the active region) is formed by a photolithography process. Thereafter, the lower protective film 115 and the upper protective film 116, which remain on the N-type MIS transistor formation region Rₙ (the region including the active region and a part of the isolation region 101 around the active region), are removed by using the resist pattern 121 as a mask.

Then, as shown in FIG. 3B, after the resist pattern 121 is removed, a metal film comprised of a metal such as, e.g., nickel etc. is deposited over the entire surface of the semiconductor substrate 100, and a heat treatment is performed thereafter. Thus, as shown in FIG. 3C, silicon contained in the N-type source/drain region 114A, the P-type source/drain region 114B, and the silicon layer 105A of the gate electrode 106A reacts with the metal in the metal film, whereby metal silicide layers 122A, 122B, 122C comprised of, e.g., nickel silicide etc. are formed on the N-type source/drain region 114A, the P-type source/drain region 114B, and the gate electrode 106A, respectively. At the same time, as shown in FIG. 3C, the metal contained in the metal-containing layer 104B that serves as the gate electrode 106B reacts with the metal in the metal film, whereby the alloy layer 122D comprised of, e.g., an alloy of titanium nitride or tantalum nitride and nickel, etc. is formed on the gate electrode 106B. Then, the unreacted metal film is removed.

A CMIS transistor having the silicon mixed-crystal layer 120 in the P-type source/drain region 114B can be formed by the above process flow.

According to the present embodiment, the recessed portion (the second recessed portion 119) of the semiconductor substrate 100, in which the silicon mixed-crystal layer 120 serving as the P-type source/drain region 114B of the P-type MIS transistor is to be embedded, is formed without forming on the gate electrodes 106A, 106B of the transistors a hard mask configured to prevent selective epitaxial growth on the gate electrode as in the related art. Accordingly, when forming the N-type source/drain region 114A of the N-type MIS transistor, impurities are introduced also into the silicon layer 105A of the gate electrode 106A of the N-type MIS transistor, and thus the resistance of the gate electrode 106A can be reduced.

According to the present embodiment, since no hard mask is formed on the gate electrodes 106A, 106B, the step of removing the hard mask on the gate electrode in the related art is not required. Thus, the insulating sidewall spacers 111A, 111B can be prevented from being removed in this step. This eliminates the need for the step of forming the insulating sidewall spacers again, which is required in the related art to perform the silicidation process on the source/drain regions. Accordingly, the number of steps is not increased.

Moreover, according to the present embodiment, the silicon layer 105B of the gate electrode 106B of the P-type MIS transistor is removed when forming the recessed portion (the second recessed portion 119) of the semiconductor substrate 100 in which the silicon mixed-crystal layer 120 is to be embedded. Accordingly, the height of the gate electrode 106B is lower than that of the gate electrode 106A of the N-type MIS transistor. Since the semiconductor device having different gate electrode heights between the N-type MIS transistor and the P-type MIS transistor can be manufactured, optimal stress in a vertical direction (a direction perpendicular to the principal surface of the substrate) can be applied to the channel region of each transistor by using a liner insulating layer, whereby driving capability of each transistor can be improved.

As described above, according to the present embodiment, the performance of the semiconductor device can be improved by a strain technique using a silicon mixed-crystal layer, without increasing the gate electrode resistance and the number of steps.

The first embodiment is described with respect to an example in which the silicon mixed-crystal layer 120 (specifically, the silicon germanium layer) is provided in every P-type MIS transistor formation region Rₚ. Alternatively, however, a P-type MIS transistor having no silicon mixed-crystal layer 120 (that is, having the same gate electrode height as that of the N-type MIS transistor) may be formed by providing the opening of the resist pattern 117 only on a given one of the P-type MIS transistor formation regions Rₚ in the step of patterning the lower protective film 115 and the upper protective film 116 as shown in FIG. 2A. Such a semiconductor device can be obtained by, e.g., changing the N-type MIS transistor formation region Rₙ to the P-type MIS transistor formation region (having no silicon mixed-crystal layer) and changing the conductivity type of each component etc. accordingly in the manufacturing method of the semiconductor device according to the first embodiment shown in FIGS. 1A-1D, 2A-2D, and 3A-3C.

In the first embodiment, the silicon germanium layer (the SiGe layer) is formed as the silicon mixed-crystal layer 120 that serves as the P-type source/drain region 114B of the P-type MIS transistor. Since compressive stress can be applied to the channel region of the P-type MIS transistor in the gate length direction, carrier mobility can be enhanced, and performance can be improved. Alternatively, however, a silicon carbide (SiC) layer, for example, may be formed as the silicon mixed-crystal layer that serves as the N-type source/drain region of the N-type MIS transistor. In this case, since tensile stress can be applied to the channel region of the N-type MIS transistor in the gate length direction, carrier mobility can be enhanced, and performance can be improved. Such a semiconductor device can be obtained by, e.g., switching the N-type MIS transistor formation region Rₙ with the P-type MIS transistor formation region Rₚ, changing the conductivity type of each component etc. accordingly, and forming, e.g., a SiC layer (doped with N-type impurities) instead of the SiGe layer as the silicon mixed-crystal layer 120 in the manufacturing method of the semiconductor device according to the first embodiment shown in FIGS. 1A-1D, 2A-2D, and 3A-3C.

### Modification of First Embodiment

A semiconductor device according to a modification of the first embodiment and a manufacturing method thereof will be described below with reference to the drawings.

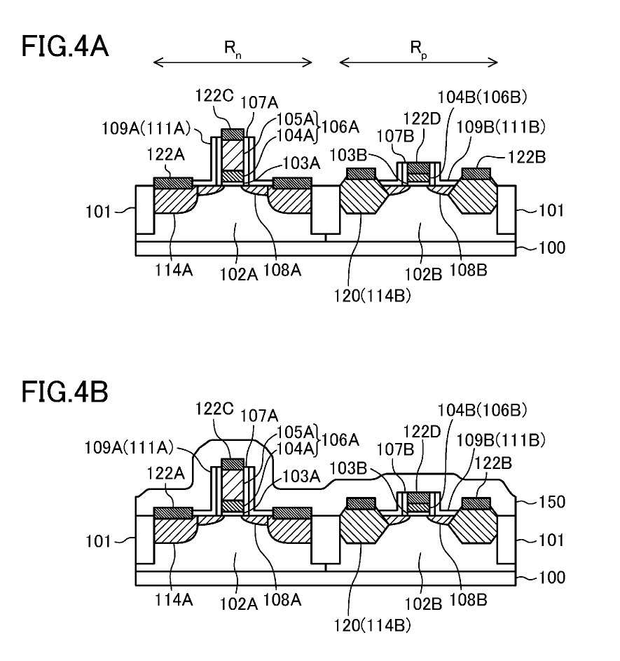

FIGS. 4A and 4B are cross-sectional view in a gate length direction, showing the steps of the manufacturing method of the semiconductor device according to the modification.

In this modification, after the steps of the manufacturing method of the semiconductor device according to the first embodiment shown in FIGS. 1A-1D, 2A-2D, and 3A-3C are performed, the outer sidewall spacers 110A, 110B of the insulating sidewall spacers 111A, 111B that are respectively formed over the side surfaces of the gate electrodes 106A, 106B are removed as shown in FIG. 4A.

Respective upper portions (the portions located above the alloy layer 122D on the gate electrode 106B) of the insulating offset spacer 107B and the L-shaped inner sidewall spacer 109B which are located on the side surface of the gate electrode 106B may be eliminated in the step shown in FIG. 4A or in the subsequent step. In this case, the height of the insulating offset spacer 107B is about the same as that of the stacked structure of the gate electrode 106B and the alloy layer 122D, and is lower than that of the insulating offset spacer 107A on the side surface of the gate electrode 106A. The height of the L-shaped inner sidewall spacer 109B (the remaining insulating sidewall spacer 111B) is also about the same as that of the stacked structure of the gate electrode 106B and the alloy layer 122D, and is lower than that of the L-shaped inner sidewall spacer 109A (the remaining insulating sidewall spacer 111A) on the side surface of the gate electrode 106A. It should be noted that the respective heights of the insulating offset spacer 107B and the L-shaped inner sidewall spacer 109B may be slightly greater than the height of the stacked structure of the gate electrode 106B and the alloy layer 122D.

Then, as shown in FIG. 4B, an insulating layer 150 (e.g., a silicon nitride film) that produces stress (i.e., tensile stress) in the opposite direction to that of the stress of the silicon mixed-crystal layer 120 is formed over the entire surface of the semiconductor substrate 100 (i.e., so as to cover the active region of the N-type MIS transistor and the active region of the P-type MIS transistor).

According to this modification, the height of the gate electrode 106B of the P-type MIS transistor (precisely, the height of the stacked structure of the gate electrode 106B and the alloy layer 122D) is lower than that of the gate electrode 106A of the N-type MIS transistor (precisely, the height of the stacked structure of the gate electrode 106A and the metal silicide layer 122C). Accordingly, even if the insulating layer 150 that produces tensile stress is formed over the entire substrate surface, stress that is applied from the insulating film 150 to the channel region of the P-type MIS transistor in the gate length direction can be reduced. Since the effect of the stress that is applied from the silicon mixed-crystal layer 120 to the channel region of the P-type MIS transistor is not eliminated, degradation in characteristics of the P-type MIS transistor can suppressed. Thus, the step of removing from the P-type MIS transistor the insulating layer 150 that produces stress in the opposite direction to that of the stress of the silicon mixed-crystal layer 120 can be omitted.

In particular, in the case where the height of the top portion of the silicon mixed-crystal layer 120 (precisely, the upper surface of the metal silicide layer 122B on the silicon mixed-crystal layer 120) from the substrate surface is about 10-30 nm, characteristics of the P-type MIS transistor are hardly degraded as long as the height of the stacked structure of the gate electrode 106A and the metal silicide layer 122C from the substrate surface is about 50 nm or less, even if the insulating layer 150 that produces stress in the opposite direction to that of the stress of the silicon mixed-crystal layer 120, namely tensile stress, is present on the P-type MIS transistor.

In this modification, the insulating layer 150 that produces stress in the opposite direction to that of the stress of the silicon mixed-crystal layer 120 may be formed without removing the outer sidewall spacers 110A, 110B. However, in order to effectively apply the stress from the insulating layer 150 to the channel region of the N-type MIS transistor, it is preferable to form the insulating layer 150 after removing the outer sidewall spacers 110A, 110B. In the case where the insulating layer 150 is formed after removing the outer sidewall spacers 110A, 110B as in this modification, it is preferable that the insulating layer 150 be formed to cover the bent portion of the L-shaped inner sidewall spacer 109A formed over the side surface of the gate electrode 106A of the N-type MIS transistor. This allows the stress to be more effectively applied from the insulating layer 150 to the channel region of the N-type MIS transistor, and thus the characteristics of the N-type MIS transistor can further be improved.

In this modification, the insulating layer 150 that produces tensile stress is formed over the entire substrate surface after forming the SiGe layer as the silicon mixed-crystal layer 120 that serves as the P-type source/drain region 114B of the P-type MIS transistor. Alternatively, however, effects similar to those of this modification can be produced even if an insulating layer (e.g., a silicon nitride film) that produces compressive stress is formed over the entire substrate surface after, e.g., a SiC layer is formed as the silicon mixed-crystal layer that serves as the N-type source/drain region of the N-type MIS transistor. Such a semiconductor device can be obtained by, e.g., switching the N-type MIS transistor formation region Rₙ with the P-type MIS transistor formation region Rₚ, changing the conductivity type of each component etc. accordingly, forming as the silicon mixed-crystal layer 120 a SiC layer (doped with N-type impurities) instead of the SiGe layer, and forming as the insulating film 150 an insulating layer (e.g., a silicon nitride film) that produces compressive stress, in the manufacturing method of the semiconductor device according to the first embodiment shown in FIGS. 1A-1D, 2A-2D, and 3A-3C and the manufacturing method of the semiconductor device according to this modification shown in FIGS. 4A and 4B.

The step of removing from the P-type MIS transistor formation region Rₚ the insulating film 150 that produces stress in the opposite direction to that of the stress of the silicon mixed-crystal layer 120, namely tensile stress, is omitted in this modification. Alternatively, however, the insulating layer 150 may be removed from the P-type MIS transistor formation region Rₚ. In this case, after the insulating layer 150 is removed from the P-type MIS transistor formation region Rₚ, another insulating film (e.g., a silicon nitride film) that produces stress in the same direction as that of the stress of the silicon mixed-crystal layer 120, i.e., compressive stress, may be formed over the entire substrate surface, and this insulating film may be removed from the N-type MIS transistor formation region Rₙ. This can further improve the characteristics of each transistor.

What is claimed is:

1. A semiconductor device, comprising:
a semiconductor substrate having thereon a first MIS transistor and a second MIS transistor that are separated from each other by an isolation region, wherein
the first MIS transistor includes
a first active region surrounded by the isolation region in the semiconductor substrate,
a first gate insulating film formed on the first active region,
a first gate electrode formed on the first gate insulating film,
a first insulating sidewall spacer formed on a side surface of the first gate electrode, and
a first source/drain region formed outside the first insulating sidewall spacer, as viewed from the first gate electrode, in the first active region,
the second MIS transistor includes
a second active region surrounded by the isolation region in the semiconductor substrate,
a second gate insulating film formed on the second active region,
a second gate electrode formed on the second gate insulating film,
a second insulating sidewall spacer formed on a side surface of the second gate electrode, and
a second source/drain region formed outside the second insulating sidewall spacer, as viewed from the second gate electrode, in the second active region,
the second source/drain region includes a silicon mixed-crystal layer, and
the second gate electrode has a lower height than the first gate electrode.

2. The semiconductor device of claim 1, wherein
the first gate electrode has a first metal-containing layer, and a silicon layer formed on the first metal-containing layer and containing the same impurities as the first source/drain region,
the second gate electrode has a second metal-containing layer,
a metal silicide layer is formed on the first gate electrode, and
an alloy layer is formed on the second gate electrode.

3. The semiconductor device of claim 1, wherein
a metal silicide layer is formed on each of the first and second source/drain regions.

4. The semiconductor device of claim 1, further comprising:
a first extension region formed below the first insulating sidewall spacer in the first active region; and
a second extension region formed below the second insulating sidewall spacer in the second active region.

5. The semiconductor device of claim 1, wherein
the first insulating sidewall spacer includes a first L-shaped inner sidewall spacer, and
the second insulating sidewall spacer includes a second L-shaped inner sidewall spacer.

6. The semiconductor device of claim 5, wherein
each of the first and second L-shaped inner sidewall spacers is comprised of a silicon oxide film.

7. The semiconductor device of claim 5, wherein
the second L-shaped inner sidewall spacer has a lower height than the first L-shaped inner sidewall spacer.

8. The semiconductor device of claim 5, wherein
the first insulating sidewall spacer includes a first outer sidewall spacer that covers the first L-shaped inner sidewall spacer, and
the second insulating sidewall spacer includes a second outer sidewall spacer that covers the second L-shaped inner sidewall spacer.

9. The semiconductor device of claim 8, wherein
each of the first and second outer sidewall spacers is comprised of a silicon nitride film.

10. The semiconductor device of claim 1, further comprising:
a first insulating offset spacer formed between the side surface of the first gate electrode and the first insulating sidewall spacer; and
a second insulating offset spacer formed between the side surface of the second gate electrode and the second insulating sidewall spacer.

11. The semiconductor device of claim 10, wherein
the second insulating offset spacer has a lower height than the first insulating offset spacer.

12. The semiconductor device of claim 1, wherein
a part of the silicon mixed-crystal layer overlaps the second insulating sidewall spacer.

13. The semiconductor device of claim 1, wherein
a top portion of the silicon mixed-crystal layer is located higher than an upper surface of the semiconductor substrate which serves as the second active region.

14. The semiconductor device of claim 1, wherein
the semiconductor substrate is a silicon substrate,
the second MIS transistor is a P-type MIS transistor, and
the silicon mixed-crystal layer is a SiGe layer.

15. The semiconductor device of claim 1, wherein
the semiconductor substrate is a silicon substrate,
the second MIS transistor is an N-type MIS transistor, and
the silicon mixed-crystal layer is a SiC layer.

16. The semiconductor device of claim 1, wherein
an insulating layer that produces stress in an opposite direction to that of stress of the silicon mixed-crystal layer is formed to cover the first and second MIS transistors.

17. The semiconductor device of claim 16, wherein
the second MIS transistor is a P-type MIS transistor, and
the insulating layer produces tensile stress.

18. The semiconductor device of claim 16, wherein
the second MIS transistor is an N-type MIS transistor, and
the insulating layer produces compressive stress.
